(19) United States
(12) Patent Application Publication
(10) Pub. No.: US 2016/0172313 A1
(43) Pub. Date: Jun. 16, 2016

(54) SUBSTRATE WITH A SUPPORTING PLATE AND FABRICATION METHOD THEREOF

(71) Applicant: NANTONG FUJITSU MICROELECTRONICS CO., LTD., NANTONG (CN)

(72) Inventor: Haiqing Zhu, Nantong (CN)

(73) Assignee: NANTONG FUJITSU MICROELECTRONICS CO., LTD.

(21) Appl. No.: 14/967,986

(22) Filed: Dec. 14, 2015

(30) Foreign Application Priority Data
Dec. 16, 2014 (CN) 2014-10781889.1
Dec. 16, 2014 (CN) 2014-10783247.5

(51) Int. Cl. H01L 23/00; H01L 23/498; H01L 21/48

(52) U.S. Cl. CPC H01L 23/562; H01L 21/481; H01L 24/83; H01L 21/4857; H01L 23/49822; H01L 23/49866; H01L 24/32; H01L 2224/83192; H01L 2224/83874; H01L 2924/15747; H01L 2224/32225

(57) ABSTRACT

A method for forming a substrate with a supporting plate includes forming a substrate including an active area and an edge area. The active area is surrounded by the edge area. The method further includes forming the supporting plate with a shape corresponding to the shape of the edge area of the substrate. The supporting plate has a bonding surface to bond the substrate. Finally, the method includes attaching the supporting plate to the substrate with the bonding surface of the supporting plate bonded to the edge area of the substrate.

### CROSS-REFERENCES TO RELATED APPLICATIONS

This application claims the priority of Chinese patent application No. 201410781889.1, filed on Dec. 16, 2014, and Chinese patent application No. 201410783247.5, filed on Dec. 16, 2014, the entirety of all of which is incorporated herein by reference.

### FIELD OF THE INVENTION

The present invention generally relates to the field of semiconductor packaging technology and, more particularly, relates to a substrate with a supporting plate to reduce substrate warpage and damage and the fabricating process thereof.

### BACKGROUND

With continuous progress of integrated circuit (IC) technology, electronic products are being developed along a direction to become more compact and more intelligent, and also have high performance and high reliability. IC packaging not only directly affects the performance of IC, the electronic module, and even the entire system, but also relates to miniaturization, cost reduction, and reliability improvement of the entire electronic system. As the chip size of IC becomes smaller while the integration level becomes higher, the electronic industry desires to have more strict requirements for IC packaging technology. These requirements lead to smaller thickness of packaging substrates.

However, a thinner substrate may result in an increased possibility of causing warpage of the substrate, damage to the edges of the substrate, and also other problems during packaging process. Warped and damaged substrate may make a subsequent packaging process inconvenient and raise the risk for the packaging process and, thus, may further affect the product yield. The disclosed substrate with the supporting plate and the fabricating process are directed to solve one or more problems set forth above and other problems.

### BRIEF SUMMARY OF THE DISCLOSURE

One aspect of the present disclosure provides a method for forming a substrate with a supporting plate. Specifically, the method includes forming a substrate including an active area and an edge area. The active area is surrounded by the edge area. The method further includes forming the supporting plate with a shape corresponding to the shape of the edge area of the substrate. The supporting plate has a bonding surface to bond the substrate. Finally, the method includes attaching the supporting plate to the substrate with the bonding surface of the supporting plate bonded to the edge area of the substrate.

Another aspect of the present disclosure includes a substrate with a supporting plate. The substrate includes a substrate having an active area and an edge area. The active area is surrounded by the edge area. The substrate also includes the supporting plate having a bonding surface to bond the substrate and a shape corresponding to a shape of the edge area of the substrate. The supporting plate is attached to the substrate with the bonding surface of the supporting plate bonded to the edge area of the substrate.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a flowchart of an exemplary fabrication process for a substrate with a supporting plate consistent with the disclosed embodiments; and

FIGS. 2-9 illustrate schematic cross-section views of semiconductor structures corresponding to certain stages of an exemplary fabrication process consistent with the disclosed embodiments.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

As described above in the background section, conventional substrates may be easily warped or damaged during packaging process. Therefore, methods in the current technology may have a full plate installed on the back of a substrate to protect the substrate. However, such a full plate may still provide insufficient protection for the substrate, and the substrate warpage may still occur. Specifically, the installed full plate may lead to a non-uniform heat distribution on the substrate and thus may even enhance the degree of substrate warping. In addition, ultimately, the full plate is usually required to be removed, and during the removal of the full plate, the substrate may be damaged.

The present disclosure provides a method for fabricating a substrate with a supporting plate to reduce the possibilities of warpage and breakage of substrates during packaging process.

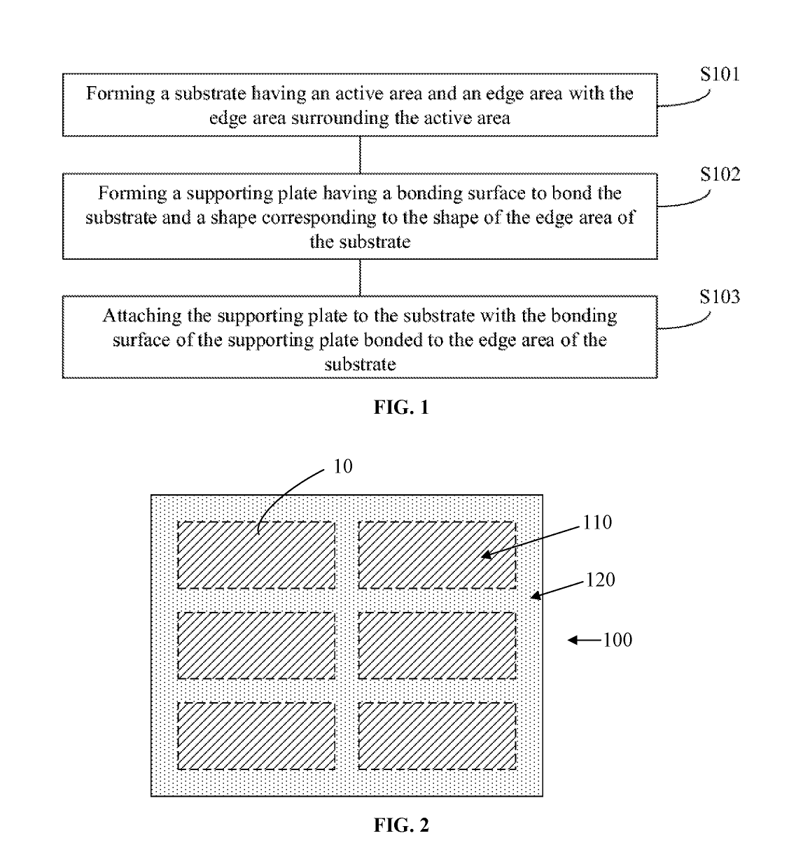

FIG. 1 shows a flowchart of an exemplary fabrication process for a substrate with a supporting plate consistent with the disclosed embodiments.

Referring to FIG. 1, at the beginning of the fabrication process, a substrate is formed (S101). FIG. 2 shows a schematic view of the substrate 100.

Referring to FIG. 2, the substrate 100 may include an active area 110 and an edge area 120. The active area 110 may be surrounded by the edge area 120 and semiconductor devices may be formed in the active area 110.

In one embodiment, the active areas 110 of the substrate 100 include a plurality of separated active area blocks 10. The plurality of the separated active area blocks 10 may be arranged in an array. Correspondingly, the edge area 120 may surround each active area block 10.

In certain other embodiments, the shape and the division of the active area 110 and the arrangement of the active area blocks 10 may be different. Coordinately, the shape and the range of the edge area 120 may also be changed in order to surround the active area 110. Therefore, the detailed shapes of the active area 110 and the edge area 120 are not limited to any specific form.

In one embodiment, the thickness of the substrate 100 may be in a range of 65˜115 μm. For example, the substrate 100 may have a thickness of ˜100 μm. However, the thickness of the substrate 100 is not limited to the range and the substrate 100 may have any appropriate thickness depending on the actual demand.

Further, returning to FIG. 1, a supporting plate with a shape corresponding to the shape of the edge area of the substrate may be formed (S102). The formation of the supporting plate may include two steps:

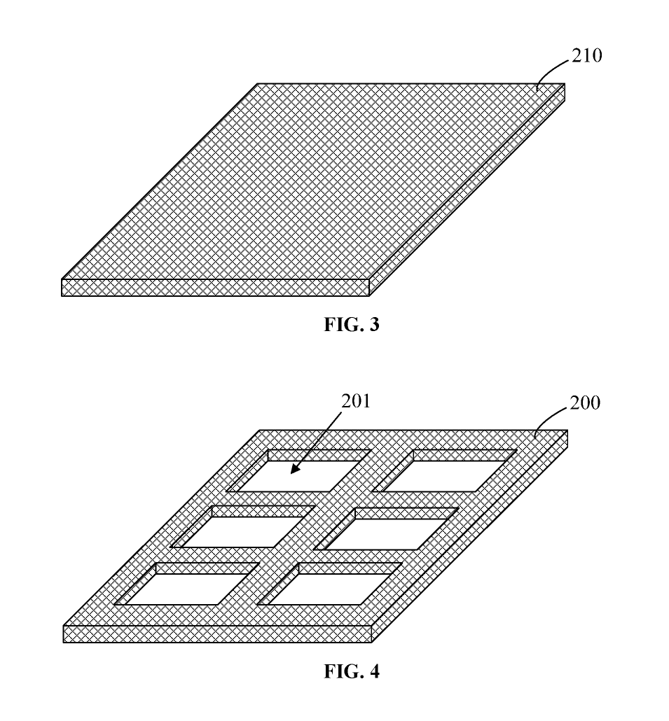

First, referring to FIG. 3, a plate of supporting material 210 may be provided. In a subsequent process, the plate of supporting material 210 may be used to form the supporting plate. The plate of supporting material 210 may be made of a resin-containing material having a relatively low thermal conductivity and relatively low heat absorption.

Then, referring to FIG. 4, a supporting plate 200 may be formed from the plate of supporting material 210 with a shape corresponding to shape of the edge area 120 in the substrate 100. Specifically, a portion of the plate of supporting material 210 corresponding to the active area 110 of the substrate may be removed, and the remained portion of the plate of supporting material 210 may have a shape corresponding to the shape of the edge area of the substrate 100, thus the supporting plate 200 may further be formed.

In one embodiment, as described above, the active area 110 of the substrate 100 (referring to FIG. 2) includes a plurality of separated active area blocks 10. As a consequence, a portion of the plate of supporting material 210 corresponding to the active area 110 of the substrate 100 may be removed to form a plurality of open-window regions 201 in the plate of supporting material 210 so that after bonding the supporting plate 200 to the substrate 100, the active area 110 may be exposed by the open-window regions 201.

Specifically, the open-window regions 201 may be formed by using a milling cutter to remove the portion of the plate of supporting material 210 corresponding to the active area 110 of the substrate 100. The method of using a milling cutter may have a relatively high cutting accuracy to ensure neat edges being formed for the open-window regions 201.

In certain other embodiments, the removal of the portion of the plate of supporting material corresponding to the active area of the substrate may be achieved by any other appropriate methods such as stamping, laser cutting, etc.

Alternatively, when the supporting plate 200 is made of a resin material, instead of forming the supporting plate 200 by removing a portion of a plate of supporting material 210, the supporting plate 200 with a shape identical to the shape of the edge area 120 of the substrate 100 may be formed through an injection molding process. First, a supporting plate mold with an empty area is provided. The shape of the empty area in the supporting plate mode corresponds to the shape of the edge area 120 of the substrate. Then, the supporting plate mold is filled by melted supporting material, i.e. the resin material to form the supporting plate. Finally, after the supporting material solidifies, the supporting plate mold is removed. As such, a supporting plate consistent with disclosed embodiments is formed by the injection molding process. Therefore, the formation of the supporting plate 200 with a shape consistent with the shape of the edge area 120 of the substrate 100 is not limited to any specific method, and an appropriate fabrication method may be selected based on the material of the supporting plate, the structure of the supporting plate, etc.

The supporting plate may include a bonding surface. In a subsequent process, the supporting plate 200 may be bonded to the substrate 100 using the bonding surface.

In one embodiment, the supporting plate 200 is made of a resin-containing material with a relatively low thermal conductivity and low heat absorption. Therefore, the amount of heat transferred to the substrate from the supporting plate 200 may be limited and thus, to a certain extent, substrate warping due to excessive heat in a local area of the substrate 100 is reduced.

The resin-containing material is light and also easy to process, thus the fabrication process may be simplified. In one embodiment, the supporting plate 200 may be made of Bismaleimide-Triazine (BT) resin or an epoxy resin.

Moreover, the supporting plate 200 may be formed by pressing an intercalated multi-layer structure of resin material and copper foil. That is, the supporting plate 200 may be a laminated plate formed by stacking resin plates and copper foils together. The structure of the laminated plate is similar to the structure of the substrate 100, thus the difference in the thermal expansion coefficients of the supporting plate 200 and the substrate 100 may be smaller. Therefore, the possibility of substrate warping caused by a non-uniform heat distribution in the substrate 100 may be reduced.

Further, the laminated plate formed by resin plates and copper foils may have relatively high mechanical strength, thus the supporting plate 200 may provide desired support for the substrate 100.

In certain other embodiments, the supporting plate 200 may be made of any other appropriate resin-containing materials. For example, the supporting plate 200 may be made of a resin material. That is, the material used to form the supporting plate 200 may be a resin-only material. In addition, the supporting plate 200 may also be a resin plate covered by a copper foil.

In one embodiment, the thickness of the supporting plate 200 may be in a range of 200˜400 μM. For example, the thickness of the supporting plate may be 300 μm. A supporting plate with such a moderate thickness may have sufficient strength to support the substrate 100.

Further, returning to FIG. 1, the supporting plate may be bonded to the edge area of the substrate using an adhesive layer (S103). The supporting plate 200 may be bonded to the edge area 120 of the substrate through the following steps:

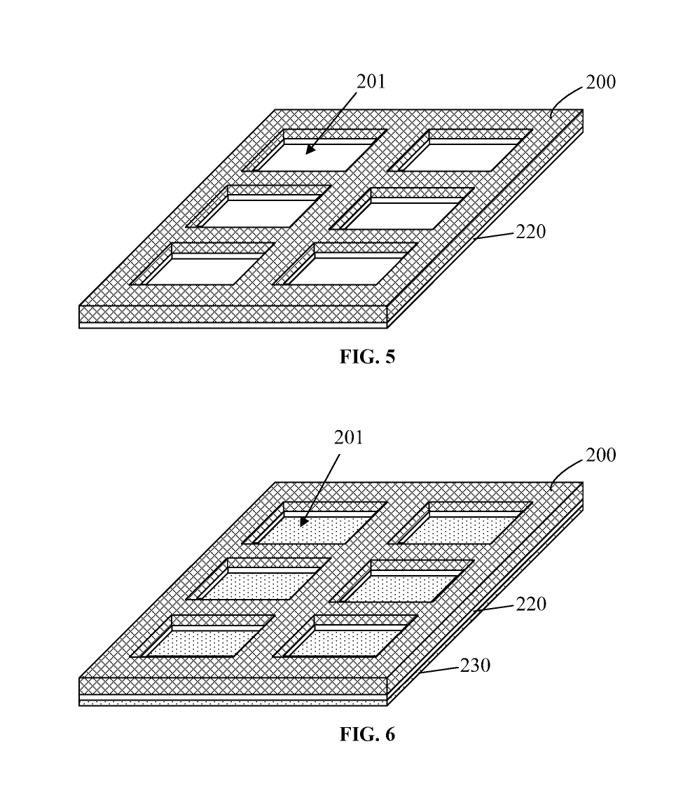

First, referring to FIG. 5, an adhesive layer 220 may be formed on the bonding surface of the supporting plate 200; then, the supporting plate 200 may be attached and bonded to the edge area 120 of the substrate 200 through the adhesive layer 220.

Specifically, the adhesive layer 220 on the bonding surface of the supporting plate 200 may be formed by coating adhesive on the bonding surface of the supporting plate 200. The adhesive used for coating may be any appropriate adhesive material. In one embodiment, the adhesive coated on the supporting plate 200 is an UV adhesive.

UV adhesive is a type of bonding material having its property changed under irradiation of ultraviolet light with a certain wavelength. UV adhesive may be further classified as two categories based on the change in the adhesion strength of the adhesive material after UV irradiation:

One category is UV curing adhesive. Specifically, for an UV curing adhesive, by absorbing UV light during UV irradiation, photoinitiators and photosensitizers in the adhesive generate active free-radicals and cations, leading to monomer polymerization, crosslinking reaction, and graft reaction. Therefore, the UV adhesive may change from a liquid state into a solid state within several seconds, thus bonding between the adhesive and the surface in contact with the adhesive may be realized.

The other category of UV adhesive has relatively strong initial adhesion prior to UV irradiation; however, the adhesion strength is significantly reduced or even vanishes due to breaking cross-link bonds in the UV adhesive during an UV irradiation process. Therefore, the adhesive may be easily peeled off from the surface in contact with the adhesive after UV irradiation.

In one embodiment, the adhesive layer 220 used to bond the supporting plate 200 and the edge area 120 of the substrate 200 is made of an UV curing adhesive. In certain other embodiments, the adhesive layer 220 may also be made of BAC polymeric self-adhesive and other types of adhesive. Further, the adhesive layer 220 may be formed by curing the coated adhesive.

In one embodiment, referring to FIG. 6, a protective film 230 may be formed on the surface of the adhesive layer 220 to prevent the adhesive layer 220 from losing adhesive ability due to absorbing dust or other contaminations onto the surface or experiencing collisions during the time period of the adhesive layer 220 exposed in a production environment.

Correspondingly, before bonding the supporting plate 200 to the substrate 100, the protective film 230 may be teared off to expose the adhesive layer 220. The supporting plate 200 is then bonded to the edge area 120 of the substrate 100 through the adhesive layer 220.

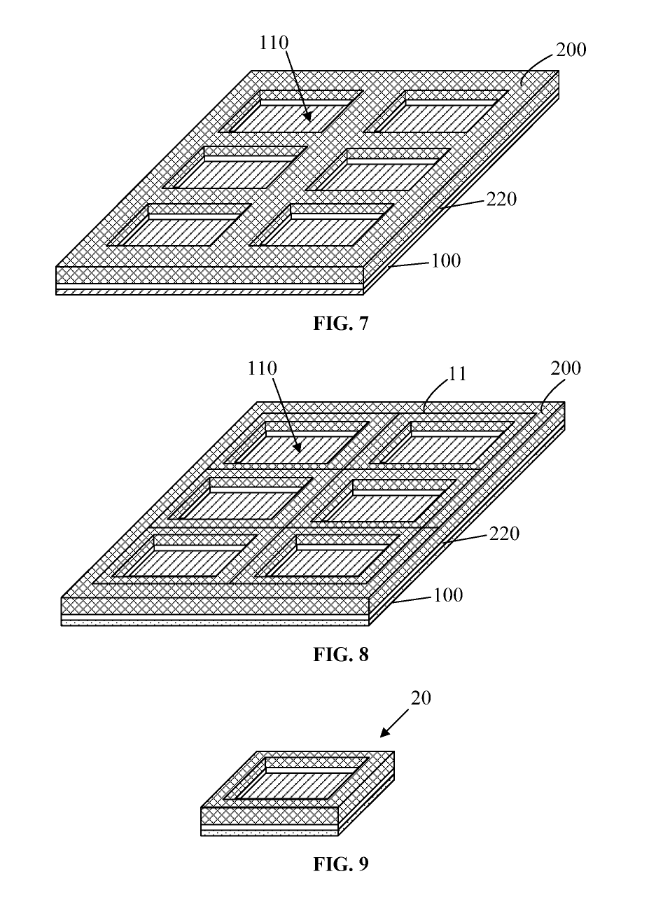

FIG. 7 shows a schematic view of the structure with the supporting plate 200 bonded to the substrate 100. In one embodiment, as described above, the protective film 230 is removed and the supporting plate 200 is bonded to the edge area 120 of the substrate 100 through the adhesive layer 220. Therefore, the supporting plate 200 reinforces and supports the substrate 100, thus preventing the substrate 100 from being warped or being damaged. In the meantime, the supporting plate 200 and the substrate 100 may be mutually bonded together and never need to be separated afterwards. Therefore, as compared to methods in current technology that require an extra process to remove a pre-installed full plate, the disclosed method may reduce the possibility of substrate damage or breakage.

After bonding the supporting plate 200 and the substrate 100 together, the bonded substrate 100 and the supporting plate 200 may further be divided into a plurality of packaging units.

FIG. 8 shows a schematic diagram to divide the bonded structure including the substrate 100 and the supporting plate 200 into individual packaging units. Referring to FIG. 8, a plurality of regions corresponding to the active area blocks 10 in the substrate 100 may be defined in the bonded structure of the supporting plate 200 and the substrate 100. Specifically, a plurality of dividing lines 11 may divide the substrate 100 and the supporting plate 200 into the plurality of regions.

FIG. 9 shows a schematic view of an individual packaging unit 20 formed by dividing the substrate 100 and the supporting plate 200 into pieces corresponding to the plurality of active area blocks 10 in the substrate 100. The separated individual packaging units 20 may facilitate the follow-up packaging process. In certain other embodiments, the bonded substrate 100 and the supporting plate 200 may not be divided into small packaging units.

The present disclosure also provides a substrate with a supporting plate. FIG. 7 shows a schematic view of the substrate with the supporting plate. Referring to FIG. 7, the substrate with the supporting plate includes a substrate 100.

Returning to FIG. 2, the substrate 100 further includes an active area 110 and an edge area 120 surrounding the active area 110. Semiconductor devices may be formed on the active area 110 of the substrate 100.

In one embodiment, the active area 110 of the substrate 100 includes a plurality of separated active area blocks 10. The plurality of separated active area blocks 10 may be arranged into an array. Correspondingly, the edge area 120 may surround each active area block 10.

In certain other embodiments, the shape and the division of the active area 110 and the arrangement of the active area blocks may be different. Coordinately, the shape and the range of the edge area 120 may also be changed in order to surround the active area 110. Therefore, the detailed shapes of the active area 110 and the edge area 120 are not limited to any specific form.

In one embodiment, the thickness of the substrate 100 may be in a range of 65˜115 μm. For example, the substrate 100 may have a thickness of ˜100 μm. However, the thickness of the substrate 100 is not limited to the range and the substrate 100 may have any appropriate thickness depending on the actual demand.

Returning to FIG. 7, the disclosed substrate with the supporting plate also includes a supporting plate 200.

Referring to FIG. 4, the supporting plate 200 may have a shape corresponding to the shape of the edge area 120 of the substrate 100. That is, the supporting plate 200 may include a plurality of open-window regions 201 corresponding to the active area blocks 10 of the substrate 100. The supporting plate 200 may also include a bonding surface. In a subsequent process, the supporting plate 200 may be bonded to the substrate 100 using the bonding surface.

In one embodiment, the supporting plate 200 is made of a resin-containing material with a relatively low thermal conductivity and low heat absorption. Therefore, the amount of heat transferred to the substrate from the supporting plate 200 may be limited and thus, to a certain extent, substrate warping due to excessive heat in a local area of the substrate 100 is reduced.

The resin-containing material is light and also easy to process, thus the fabrication process may be simplified. In one embodiment, the supporting plate 200 may be made of Bismaleimide-Triazine (BT) resin or an epoxy resin.

Moreover, the supporting plate 200 may be formed by pressing an intercalated multi-layer structure of resin material and copper foil. That is, the supporting plate 200 may be a laminated plate formed by stacking resin plates and copper foils together. The structure of the laminated plate is more close to the structure of the substrate 100, thus the difference in the thermal expansion coefficients of the supporting plate 200 and the substrate 100 may be smaller. Therefore, the possibility of substrate warping caused by a non-uniform heat distribution in the substrate 100 may be reduced.

Further, the laminated plate formed by resin plates and copper foils may have relatively high mechanical strength, thus the supporting plate 200 may provide desired support for the substrate 100.

In certain other embodiments, the supporting plate 200 may be made of any other appropriate resin-containing materials. For example, the supporting plate 200 may be made of a resin material. That is, the material used to form the supporting plate 200 may be a resin-only material. In addition, the supporting plate 200 may also be a resin plate covered by a copper foil.

In one embodiment, the thickness of the supporting plate 200 may be in a range of 200˜400 μm. For example, the thickness of the supporting plate may be 300 μm. A supporting plate with such a moderate thickness may have sufficient strength to support the substrate 100.

The supporting plate 200 may be made by a cutting or stamping process. In certain other embodiments, the supporting plate 200 may be made by any other appropriate process. For example, when the supporting plate 200 is made of a resin material, the supporting plate 200 may be formed through an injection molding process.

Returning to FIG. 7, the substrate with the supporting plate may also include an adhesive layer 220. Referring to FIG. 5, the adhesive layer 220 may be formed on the bonding surface of the supporting plate 200. The supporting plate 200 may be bonded to the edge area 120 of the substrate 100 using the adhesive layer 220. That is, the supporting plate 200 and the edge area 120 of the substrate 100 are bonded together to reinforce and support the substrate 100. In the meantime, the supporting plate also allows the exposure of the active area 110 of the substrate and, thus, avoids affecting the performance of the subsequent packaging process.

It should be noted that the disclosed fabrication method is not limited to the formation of the disclosed substrate with the supporting plate. The disclosed fabrication method may be adopted for forming other semiconductor structures. For example, a substrate having two supporting plates individually arranged on the two opposite surfaces of the substrate may be formed by the disclosed method. In such a case, each side of the substrate may have an active area and semiconductor devices may be formed on both active areas.

Compared to the method and the substrate in the current technology, the disclosed fabrication method and the disclosed substrate with the supporting plate may demonstrate the following advantages:

First, by providing a supporting plate with a shape identical to that of the edge area of the substrate and by further bonding the supporting plate to the substrate, the supporting plate may reinforce the edge area of the substrate and thus, to a certain extent, avoid substrate warping. In the meantime, the supporting plate and the substrate may be mutually bonded together and never need to be separated afterwards. Therefore, as compared to methods in current technology that require an extra process to remove a pre-installed full plate, the disclosed method may reduce the possibility of substrate damage or breakage.

Further, providing a supporting plate made of a resin-containing material may further reduce the possibility of substrate warping. Specifically, because of the low heat absorption rate of resin material, the amount of heat absorbed through the contact areas between the supporting plate and the substrate may be relatively small, therefore heat absorbed in different areas of the substrate may vary just slightly and, thus, substrate warping due to a non-uniform heat distribution may not likely occur in such a substrate.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a substrate with a supporting plate, comprising:
forming a substrate including an active area and an edge area with the edge area surrounding the active area;
forming the supporting plate having a bonding surface to bond the substrate and a shape corresponding to a shape of the edge area of the substrate; and
attaching the supporting plate to the substrate with the bonding surface of the supporting plate bonded to the edge area of the substrate.

2. The method according to claim 1, wherein the supporting plate is made of a resin-containing material.

3. The method according to claim 2, wherein the supporting plate is a resin-only plate, a copper foil covered resin plate, or a laminated plate formed by pressing an intercalated multi-layer structure of resin material and copper foil.

4. The method according to claim 1, wherein forming the supporting plate further includes:
providing a supporting plate mold with an empty area, wherein the shape of the empty area corresponds to the shape of the edge area of the substrate;
filling melted supporting material into the supporting plate mold to form the supporting plate; and
removing the supporting plate mold after the formation of the supporting plate.

5. The method according to claim 1, wherein forming the supporting plate further includes:
providing a plate of supporting material; and
removing a portion of the plate of supporting material corresponding to the active area of the substrate to form the supporting plate with the remained portion of the plate of supporting material.

6. The method according to claim 5, wherein the portion of the plate of supporting material is removed by mill cutting, stamping, or laser cutting.

7. The method according to claim 1, wherein:
the active area of the substrate further includes a plurality of separated active area blocks;
the plurality of active area blocks are arranged into an array forming; and
the edge area of the substrate surrounds each active area block.

8. The method according to claim 7, wherein the supporting plate includes a plurality of open-window regions corresponding to the plurality of active area blocks in the substrate.

9. The method according to claim 1, wherein attaching the supporting plate to the substrate further includes:
forming an adhesive layer on the bonding surface of the supporting plate; and
bonding the supporting plate to the edge area of the substrate using the adhesive layer.

10. The method according to claim 9, wherein forming an adhesive layer on the bonding surface further includes:
coating adhesive on the bonding surface of the supporting plate; and
forming the adhesive layer after curing the coated adhesive.

11. The method according to claim 10, wherein forming the adhesive layer further includes forming a protective film to cover the adhesive layer.

12. The method according to claim 11, wherein attaching the supporting plate to the substrate further includes removing the protective film before bonding the supporting plate to the edge area of the substrate.

13. A substrate with a supporting plate, comprising:
a substrate having an active area and an edge area with the edge area surrounding the active area; and
a supporting plate having a bonding surface to bond the substrate and a shape corresponding to a shape of the edge area of the substrate, wherein:
the supporting plate is attached to the substrate with the bonding surface of the supporting plate bonded to the edge area of the substrate.

14. The substrate with the supporting plate according to claim 13, wherein the thickness of the supporting plate is in a range of 200˜400 μm.

15. The substrate with the supporting plate according to claim 13, wherein the supporting plate is made of a resin-containing material.

16. The substrate with the supporting plate according to claim 13, wherein the supporting plate is a resin-only plate, a copper foil covered resin plate, or a laminated plate formed by pressing an intercalated multi-layer structure of resin material and copper foil.

17. The substrate with the supporting plate according to claim 13, wherein:
the active area of the substrate further includes a plurality of separated active area blocks;
the plurality of active area blocks are arranged into an array forming; and
the edge area of the substrate surrounds each active area block.

18. The substrate with the supporting plate according to claim 17, wherein the supporting plate includes a plurality of open-window regions corresponding to the plurality of active area blocks in the substrate.

19. The substrate with the supporting plate according to claim 13, wherein the bonding surface of the supporting plate further includes an adhesive layer and the bonding surface of the supporting plate is bonded to the edge area of the substrate through the adhesive layer.

20. The substrate with the supporting plate according to claim 19, wherein the adhesive layer is made of an UV curing adhesive.
